(19) United States
(12) Patent Application Publication
(10) Pub. No.: US 2013/0075731 A1
(43) Pub. Date: Mar. 28, 2013

(54) MANUFACTURING METHOD FOR THIN FILM TRANSISTOR AND THIN FILM TRANSISTOR MANUFACTURED BY THEM

(71) Applicants: Min Koo Han, Seoul (KR); Sun Jae Kim, Seoul (KR)

(72) Inventors: Min Koo Han, Seoul (KR); Sun Jae Kim, Seoul (KR)

(73) Assignee: SNU R&DB FOUNDATION, Seoul (KR)

(21) Appl. No.: 13/311,698

(22) Filed: Dec. 6, 2011

(30) Foreign Application Priority Data
Sep. 27, 2011 (KR) 10-2011-0097595

(51) Int. Cl. H01L 21/336; H01L 29/786; H01L 29/04

(52) U.S. Cl. 257/57; 438/158; 257/66; 257/E29.003; 257/E29.273; 257/E21.414

(57) ABSTRACT

Provided are a manufacturing method for a thin film transistor, and a thin film transistor manufactured by the manufacturing method. In the manufacturing method, a semiconductor layer and an insulating layer for stopping etching, which are sequentially stacked, are etched by dry etching and wet etching using a single photoresist pattern, and patterning the semiconductor layer and the insulating layer into a channel layer and an etch stop layer, respectively, thereby simplifying the manufacturing process of the thin film transistor.

### CROSS-REFERENCE TO RELATED APPLICATION

This application claims priority to and the benefit of Korean Patent Application No. 10-2011-0097595 filed on Sep. 27, 2011, which is herein incorporated by reference in its entirety.

### BACKGROUND OF THE INVENTION

1. Field of the Invention

The present invention relates generally to a manufacturing method for a thin film transistor and a thin film transistor manufactured thereby.

2. Description of the Related Art

A thin film transistor is used in displays and a wide variety of application fields. In the thin film transistor, a channel layer comprised of a source, a drain and a channel region may be formed of silicon or an oxide semiconductor.

A top portion of the channel layer of the thin film transistor may be damaged due to over etching using an etching gas or an etching solution when source/drain patterns are formed on the channel layer. In order to prevent the channel layer from being damaged, the thin film transistor may further include an etch stop layer on the channel layer.

However, the thin film transistor including the etch stop layer can prevent the channel layer from being damaged, may require additional process steps, including exposing and developing a separate photoresist pattern for forming the etch stop layer, etching using the photoresist, removing the photoresist pattern, etc., and the manufacturing cost may increase.

### SUMMARY OF THE INVENTION

Aspects of the present invention provide a manufacturing method for a thin film transistor, which can simplify the manufacturing process by forming a channel layer and an etch stop layer using two steps of etching using a single photoresist pattern, and a thin film transistor manufactured by the manufacturing method.

In accordance with one aspect of the present invention, there is provided a manufacturing method for a thin film transistor, the manufacturing method including preparing a substrate having a gate such that a gate insulating layer covering the gate and the substrate, a semiconductor layer and an insulating layer for stopping etching are sequentially formed on the substrate, forming a photoresist pattern such that the photoresist pattern is formed on the insulating layer for stopping etching, the photoresist pattern having a pattern corresponding to the gate, firstly etching such that the insulating layer for stopping etching and the semiconductor layer are etched using the photoresist pattern as a mask and patterned into an etch stop layer and a channel layer, respectively, secondly etching such that side surfaces of the etch stop layer disposed between the photoresist pattern and the channel layer are etched to expose opposite sides of the channel layer to the outside, removing a photoresist such that the photoresist pattern on the etch stop layer is removed, and forming a source/drain such that a source and a drain are formed at the opposite sides of the channel layer exposed to the outside in the secondly etching.

In the secondly etching, the side surfaces of the etch stop layer may be removed by wet etching.

In the secondly etching, the side surfaces of the etch stop layer may be etched 0.05 μm to 0.15 μm using a wet etching solution in the wet etching.

The wet etching solution may have larger etching selectivity to the etch stop layer than to the gate insulating layer.

In the firstly etching, the insulating layer for stopping etching and the semiconductor layer may be patterned by dry etching using the photoresist pattern as a mask.

After the forming of the source/drain, the manufacturing method may further include forming a passivation layer and contacts such that the passivation layer is formed to cover the etch stop layer and the source/drain, the passivation layer is patterned to expose the source/drain, and contacts electrically connected to the exposed source/drain are formed.

As described above, in the manufacturing method for a thin film transistor and a thin film transistor according to an embodiment of the present invention, the manufacturing process can be simplified by forming a channel layer and an etch stop layer using two steps of etching using a single photoresist pattern.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is a flow chart illustrating a manufacturing method for a thin film transistor according to an embodiment of the present invention; and

FIGS. 2A through 2J are cross-sectional views illustrating the manufacturing method shown in FIG. 1.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, a method for fabricating a thin film transistor according to an embodiment of the present invention will be described.

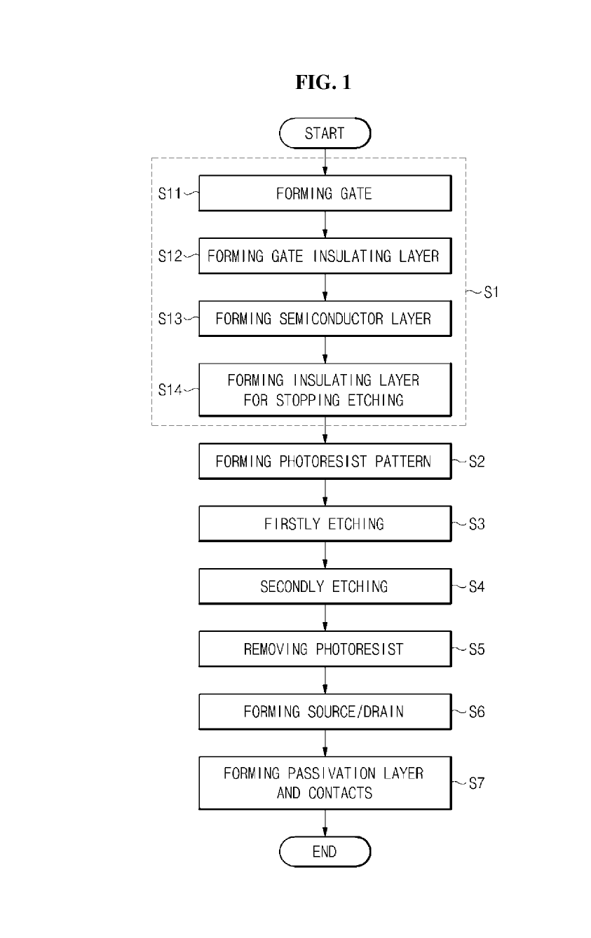

FIG. 1 is a flow chart illustrating a manufacturing method for a thin film transistor according to an embodiment of the present invention.

As shown in FIG. 1, the manufacturing method for a thin film transistor includes preparing substrate step (S1), forming photoresist pattern step (S2), firstly etching step (S3), secondly etching step (S4), removing photoresist step (S5), forming source/drain step (S6), and forming passivation layer and contacts step (S7).

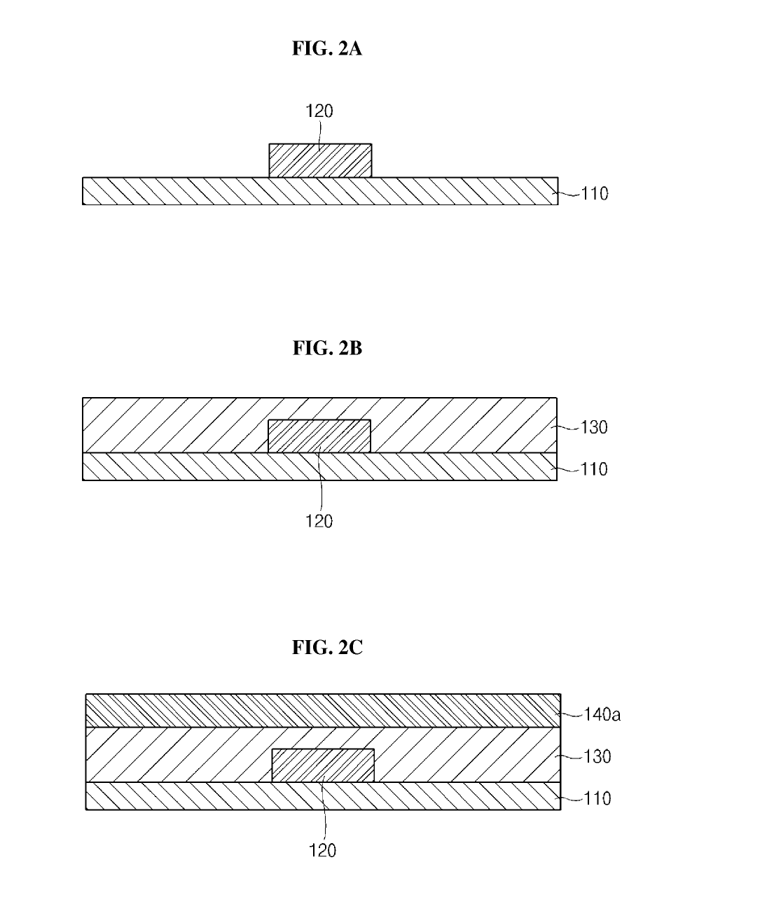

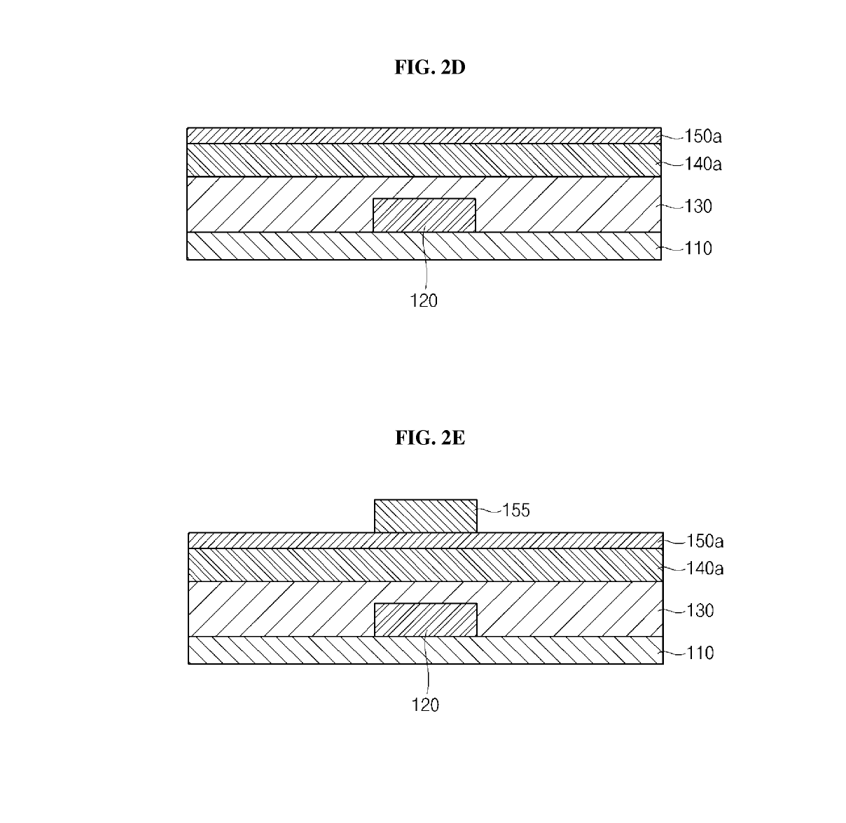

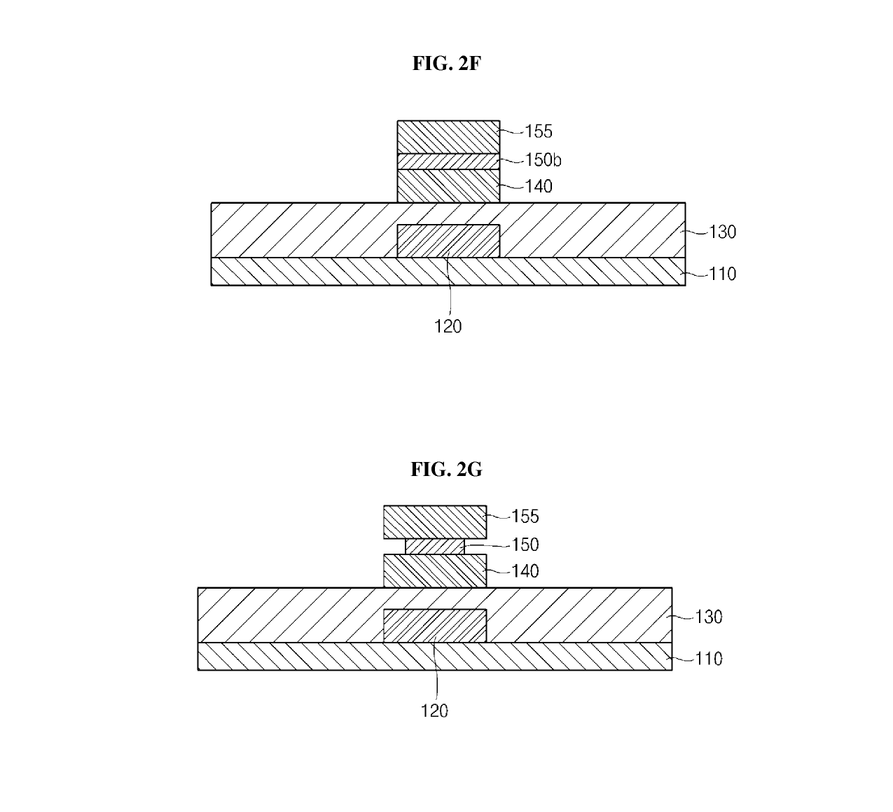

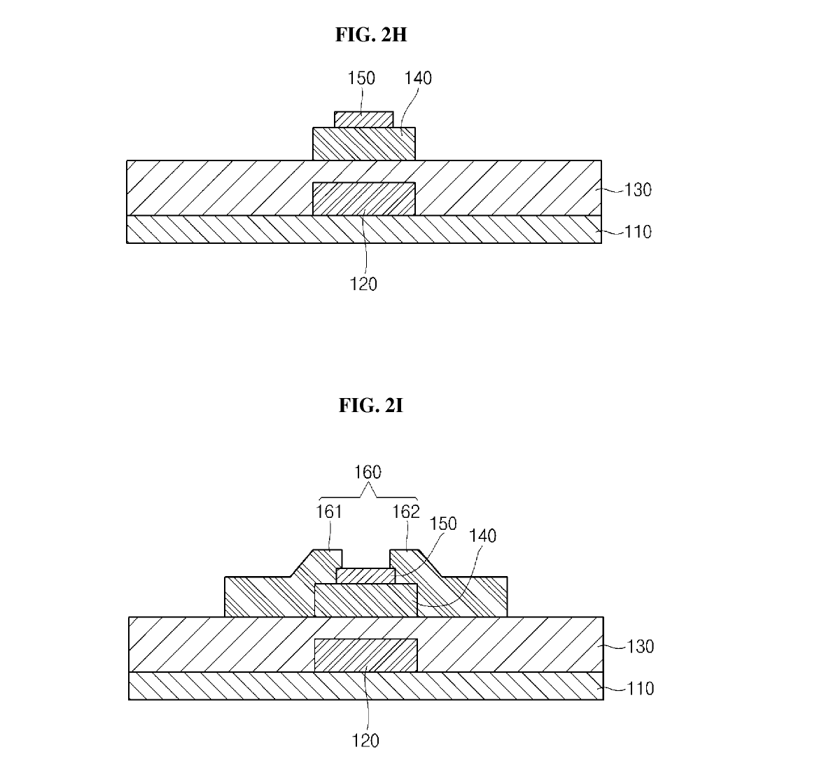

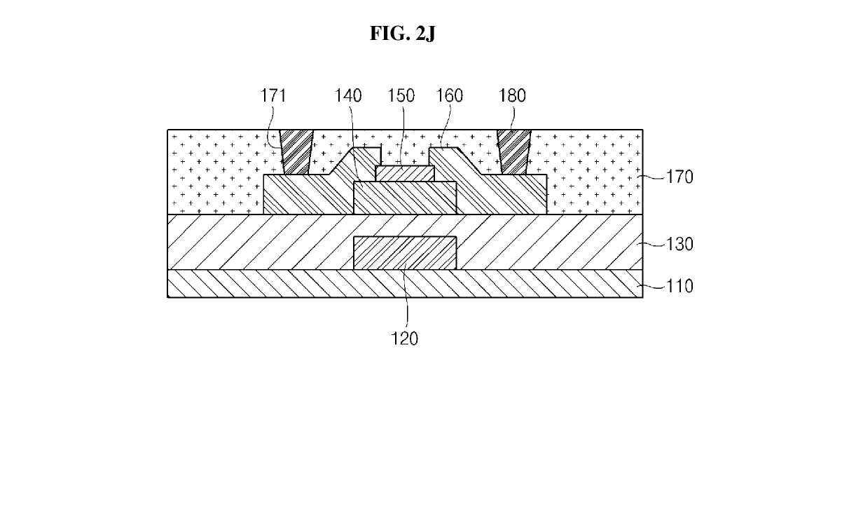

The manufacturing method for a thin film transistor will now be described in detail with reference to FIGS. 2A through 2J.

As shown in FIGS. 2A through 2D, in the preparing substrate step (S1), a gate 120, a gate insulating layer 130, a semiconductor layer 140a and an insulating layer 150a for stopping etching are sequentially formed on a substrate 110. The preparing substrate step (S1) includes forming gate step (S11), forming gate insulating layer step (S12), forming semiconductor layer step (S13), and forming insulating layer for stopping etching step (S14).

First, as shown in FIG. 2A, in the forming gate step (S11) of the preparing substrate step (S1), the gate 120 having a predetermined pattern is formed on the substantially flat substrate 110. Here, the substrate 110 may be formed of silicon, glass, plastic, sapphire, quartz, crystal, a flexible polymer, acryl, and equivalents thereof. It should be noted that the listing of the above materials should not be seen as to limit the scope of the present invention. Other materials may be used without departing from the spirit and scope of the present invention. Before forming the gate 120, a buffer layer made of silicon oxide (SiOₓ) or silicon nitride (SiNₓ) may further be formed on the substrate 110.

The gate 120 may be formed by depositing a metal layer for forming a gate on a top surface of the substrate 110 and patterning the same. The gate 120 may be formed of a conductive material, including a metal such as Ti, Pt, Ru, Au, Ag, Mo, Al, W or Cu, or a metal or conductive oxide such as indium zinc oxide (IZO), indium tin oxide (ITO) or aluminum zinc oxide (AZO). However, the present invention is not limited to such materials.

As shown in FIG. 2B, the forming gate insulating layer step (S12) of the preparing substrate step (S1), the gate insulating layer 130 is formed to cover the gate 120 formed on the substrate 110 and the top surface of the substrate 110. The gate insulating layer 130 may be formed by coating an insulating layer to a predetermined thickness to cover the gate 120 and the top surface of the substrate 110 and planarizing the same. Here, the top surface of the gate insulating layer 130 may be substantially flat. The gate insulating layer 130 may be formed of silicon dioxide (SiO₂), alumina (Al₂O₃), hafnium dioxide (HfO₂), zirconia (ZrO₂), silicon oxynitride (SiOₓN_{y}), silicon nitride (SiNₓ), an organic material, or equivalents thereof. It should be noted that the listing of the above materials should not be seen as to limit the scope of the present invention. Other materials may be used without departing from the spirit and scope of the present invention.

As shown in FIG. 2C, in the forming semiconductor layer step (S13) of the preparing substrate step (S1), the semiconductor layer 140a having a predetermined thickness is formed on the gate insulating layer 130 formed on the substrate 110 and the gate 120. The semiconductor layer 140a may be formed of one of amorphous silicon (Si), polycrystalline silicon (Poly Si) and an oxide semiconductor. Here, the oxide semiconductor may be formed of ZnO, GaInZno (GIZO), HfInZnO (HIZO), equivalents thereof. However, the present invention is not limited to such materials.

As shown in FIG. 2D, in the forming insulating layer for stopping etching step (S14) of the preparing substrate step (S1), the insulating layer 150a for stopping etching, having a predetermined thickness, is formed on the semiconductor layer 140a. The insulating layer 150a for stopping etching may be formed of silicon oxide (SiOx), silicon nitride (SiNx), aluminum oxide (AlxOx), silicon oxynitride (SiOxNy), fluorinated silicon oxide (SiOF), silicon oxycarbide (SiOC), an organic material, an insulating inorganic material, or equivalents thereof. It should be noted that the listing of the above materials should not be seen as to limit the scope of the present invention. Other materials may be used without departing from the spirit and scope of the present invention.

As shown in FIG. 2E, in the forming photoresist pattern step (S2), a photoresist pattern 155 having a pattern corresponding to the gate 120 is formed on the insulating layer 150a for stopping etching. In detail, in the forming photoresist pattern step (S2), the photoresist pattern 155 is formed by coating photoresist to a predetermined thickness and patterning the same using the pattern corresponding to the gate 120 through exposing and developing. The photoresist pattern 155 may be formed of one selected from the group consisting of a novolac resin, a photosensitive agent, a solvent, poly hydroxy styrenes (PHS) and equivalents thereof. However, the present invention is not limited to such materials.

As shown in FIG. 2F, in the firstly etching step (S3), the insulating layer 150a for stopping etching and the semiconductor layer 140a are etched using the photoresist pattern 155 formed in the forming photoresist pattern step (S2) as a mask. The insulating layer 150a for stopping etching and the semiconductor layer 140a are etched using the photoresist pattern 155 as a mask. Accordingly, the insulating layer 150a is patterned into an etch stop layer 150b having a pattern corresponding to the photoresist pattern 155 and the semiconductor layer 140a is patterned into a channel layer 140 having a pattern corresponding to the photoresist pattern 150a and the etch stop layer 150b. In the firstly etching step (S3), the etching using the photoresist pattern 155 may be dry etching using plasma or ions.

As shown in FIG. 2G, in the secondly etching step (S4), side surfaces of the etch stop layer 150b disposed between the photoresist pattern 155 and the channel layer 140 are selectively etched. In the secondly etching step (S4), the selective etching of side surfaces of the etch stop layer 150b may be wet etching using a wet etching solution. Here, the side surfaces of the etch stop layer 150b are etched 0.05 μm to 0.15 μm and then patterned into an etch stop layer 150. As described above, as the side surfaces of the etch stop layer 150b are etched and then patterned into the etch stop layer 150, opposite sides of the channel layer 140 positioned under the etch stop layer 150 are exposed to the outside. That is to say, as the side surfaces of the etch stop layer 150b are etched, a flat surface of the etch stop layer 150 is smaller than that of the channel layer 140. Accordingly, the width of the etch stop layer 150 is smaller than the width of the channel layer 140. That is, portion of the top surface of the channel layer 140 is not covered by the etch stop layer 150 after the secondly etching step (S4).

Here, the wet etching solution may have larger etching selectivity to the etch stop layer 150b than to the gate insulating layer 130. This is because the gate insulating layer 130 is etched while the side surfaces of the etch stop layer 150b are etched using the wet etching solution in the secondly etching step (S4) to prevent the gate 120 from being exposed to the outside.

As described above, in the forming photoresist pattern step (S2), the firstly etching step (S3) and the secondly etching step (S4), the channel layer 140 and the etch stop layer 150 are formed by two steps of etching using the photoresist pattern 155, thereby simplifying the manufacturing process. That is to say, since the etch stop layer 150 is patterned by wet etching without performing coating, exposing and developing of a separate photoresist for forming the etch stop layer 150, the manufacturing process of a thin film transistor can be simplified.

As shown in FIG. 2H, in the removing photoresist step (S5), the photoresist pattern 155 disposed on the etch stop layer 150 is removed. Accordingly, the entire top surface of the etch stop layer 150 is exposed. Here, the photoresist pattern 115 may be removed by one selected from the group consisting of a sulfuric acid solution, oxygen plasma and equivalents thereof, but aspects of the present invention are not limited thereto.

As shown in FIG. 2I, in the forming of source/drain step (S6), a metal layer having a predetermined thickness is formed on the gate insulating layer 130, the channel layer 140 and the etch stop layer 150. The metal layer is patterned to expose portion of the etch stop layer 150 to form a source 161 and a drain 162. Here, the source/drain 160 is formed at the opposite sides of the channel layer 140 exposed when the side surfaces of the etch stop layer 150 are etched in the secondly etching (S4). The etch stop layer 150 may prevent the channel layer 140 from being damaged by etching for patterning the metal layer into the source/drain 160 in the forming source/drain step (S6).

As shown in FIG. 2J, in the forming passivation layer and contacts step (S7), a passivation layer 170 is formed on the entire exposed top surface of the substrate 110 having the source/drain 160, and the passivation layer 170 is patterned to form contact holes 171 exposing electrodes of the source/drain 160. In addition, a contact layer is formed on the passivation layer 170 to fill the contact holes 171 and patterned to form contacts 180. Here, the passivation layer 170 may have a single layered structure or multi layered structure including one of silicon oxide (SiOx), silicon nitride (SiNx) and an organic material. However, the present invention is not limited to such materials. After the forming passivation layer and contacts step (S7), in order to connect the electrodes of thin film transistor, the manufacturing method for a thin film transistor may further include forming an electrode layer (not shown) electrically connected to the contacts 180 and an interlayer dielectric layer (not shown) for electrically disconnecting the electrode layer to have a single layered structure or multi layered structure.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A manufacturing method for a thin film transistor, comprising:
preparing a substrate having a gate such that a gate insulating layer covering the gate and the substrate, a semiconductor layer and an insulating layer for stopping etching are sequentially formed on the substrate;
forming a photoresist pattern such that the photoresist pattern is formed on the insulating layer for stopping etching, the photoresist pattern having a pattern corresponding to the gate;
firstly etching such that the insulating layer for stopping etching and the semiconductor layer are etched using the photoresist pattern as a mask and patterned into an etch stop layer and a channel layer, respectively;
secondly etching such that side surfaces of the etch stop layer disposed between the photoresist pattern and the channel layer are etched to expose opposite sides of the channel layer to the outside;
removing a photoresist such that the photoresist pattern on the etch stop layer is removed; and
forming a source/drain such that a source and a drain are formed at the opposite sides of the channel layer exposed to the outside in the secondly etching.

2. The manufacturing method of claim 1, wherein in the secondly etching, the side surfaces of the etch stop layer are removed by wet etching.

3. The manufacturing method of claim 2, wherein in the secondly etching, the side surfaces of the etch stop layer are etched 0.05 μm to 0.15 μm using a wet etching solution in the wet etching.

4. The manufacturing method of claim 3, wherein the wet etching solution has larger etching selectivity to the etch stop layer than to the gate insulating layer.

5. The manufacturing method of claim 2, wherein in the firstly etching, the insulating layer for stopping etching and the semiconductor layer are patterned by dry etching using the photoresist pattern as a mask.

6. The manufacturing method of claim 1, after the forming of the source/drain, further comprising forming a passivation layer and contacts such that the passivation layer is formed to cover the etch stop layer and the source/drain, the passivation layer is patterned to expose the source/drain, and contacts electrically connected to the exposed source/drain are formed.

7. The manufacturing method of claim 1, wherein the substrate comprises a material selected from the group consisting of silicon, glass, plastic, sapphire, quartz, crystal, a flexible polymer and acryl.

8. The manufacturing method of claim 1, wherein the gate insulating layer comprises a material selected from the group consisting of silicon dioxide (SiO₂), alumina (Al₂O₃), hafnium dioxide (HfO₂), zirconia (ZrO₂), silicon oxynitride (SiOₓN_{y}) and silicon nitride (SiNₓ).

9. The manufacturing method of claim 1, wherein the semiconductor layer comprises a material selected from the group consisting of amorphous silicon (Si), polycrystalline silicon (Poly Si) and an oxide semiconductor.

10. The manufacturing method of claim 1, wherein the insulating layer comprises a material selected from the group consisting of silicon oxide (SiOx), silicon nitride (SiNx), aluminum oxide (AlxOx), silicon oxynitride (SiOxNy), fluorinated silicon oxide (SiOF) and silicon oxycarbide (SiOC).

11. The manufacturing method of claim 1, wherein the photoresist pattern comprises a material selected from the group consisting of novolac resin, photosensitive agent, solvent and poly hydroxy styrenes (PHS).

12. The manufacturing method of claim 2, wherein in the secondly etching, a top surface of the channel layer is partially covered by the etch stop layer.

13. The manufacturing method of claim 12, wherein in the secondly etching, the width of the channel layer is greater than the width of the etch stop layer within the range of 0.1 μm to 0.3 μm.

14. The manufacturing method of claim 6, wherein in the secondly etching, the side surfaces of the etch stop layer are removed by wet etching.

15. The manufacturing method of claim 14, wherein in the secondly etching, the side surfaces of the etch stop layer are etched 0.05 μm to 0.15 μm using a wet etching solution in the wet etching.

16. The manufacturing method of claim 15, wherein the wet etching solution has larger etching selectivity to the etch stop layer than to the gate insulating layer.

17. The manufacturing method of claim 14, wherein in the firstly etching, the insulating layer for stopping etching and the semiconductor layer are patterned by dry etching using the photoresist pattern as a mask.

18. A thin film transistor comprising:
a substrate;
a gate formed on a top surface of the substrate;
a gate insulating layer covering the gate and the top surface of the substrate;
a channel layer formed on the gate insulating layer, the channel layer having a pattern corresponding to the gate;
an etch stop layer formed on the channel layer, the width of the channel layer is greater than the width of the etch stop layer;
a source/drain formed at the opposite sides of the channel layer;
a passivation layer formed on the source/drain, etch stop layer and gate insulating layer, the passivation layer having a plurality of contact holes exposing electrodes of the source/drain; and
a plurality of contacts formed in the contact holes and electrically connected to the source/drain.

19. The thin film transistor of claim 18, wherein the width of the channel layer is greater than the width of the etch stop layer within the range of 0.1 μm to 0.3 μm.

20. The thin film transistor of claim 18, wherein the etch stop layer comprises a material selected from the group consisting of silicon oxide (SiOx), silicon nitride (SiNx), aluminum oxide (AlxOx), silicon oxynitride (SiOxNy), fluorinated silicon oxide (SiOF) and silicon oxycarbide (SiOC).
